(19) United States
(12) Patent Application Publication
(10) Pub. No.: US 2021/0043427 A1
(43) Pub. Date: Feb. 11, 2021

(54) PLASMA PROCESSING APPARATUS

(71) Applicant: Tokyo Electron Limited, Tokyo (JP)

(72) Inventor: Ryo SASAKI, Miyagi (JP)

(21) Appl. No.: 16/940,734

(22) Filed: Jul. 28, 2020

(30) Foreign Application Priority Data
Aug. 5, 2019 (JP) 2019-144008

(51) Int. Cl. H01J 37/32

(52) U.S. Cl. CPC H01J 37/32495; H01J 2237/334; H01J 37/32422; H01J 37/32082

(57) ABSTRACT

There is provision of a plasma processing apparatus including a gas supply section, a first radio frequency power supply for plasma generation, a second radio frequency power supply for drawing ions, an electrode coupled to the second radio frequency power supply; and a member serving as an anode paired with the electrode. On a surface of the member, a multilayered film structure is formed to adjust capacitance of the member.

### CROSS-REFERENCE TO RELATED APPLICATIONS

This patent application is based upon and claims priority to Japanese Patent Application No. 2019-144008 filed on Aug. 5, 2019, the entire contents of which are incorporated herein by reference.

### TECHNICAL FIELD

The present disclosure relates to a plasma processing apparatus.

### BACKGROUND

The plasma processing apparatus includes a vacuum vessel which is capable of sealing the interior. For example, Patent Document 1 describes a method of generating an alumina (Al₂O₃) coating on the surface of a vacuum vessel by anodizing the surface of the vacuum vessel.

### RELATED ART DOCUMENT

### Patent Document

### [Patent Document 1] Japanese Laid-open Patent Application Publication No. 2019-071410

### SUMMARY

If coating on the inner wall of the vacuum vessel is insufficient, particles may be generated from the inner wall of the vacuum vessel due to ion bombardment, and may contaminate the interior of the vacuum vessel.

The present disclosure provides a plasma processing apparatus capable of suppressing abrasion of the inner wall of the chamber caused by ion bombardment.

According to one aspect of the present disclosure, there is provision of a plasma processing apparatus including a gas supply section, a first radio frequency power supply for plasma generation, a second radio frequency power supply for drawing ions, an electrode coupled to the second radio frequency power supply; and a member serving as an anode paired with the electrode. On a surface of the member, a multilayered film structure is formed to adjust capacitance of the member.

### BRIEF DESCRIPTION OF THE DRAWINGS

FIG. 1 is a cross-sectional diagram illustrating an example of a plasma processing apparatus according to an embodiment;

FIG. 2 is a diagram illustrating an example of an inner wall of a chamber according to the embodiment;

FIG. 3 is a diagram illustrating relative permittivities of materials to be thermal sprayed according to the embodiment;

FIGS. 4A to 4C are diagrams illustrating ion sputtering; and

FIGS. 5A to 5C are diagrams illustrating ion sputtering occurring on a multilayered film structure according to the present embodiment.

### DETAILED DESCRIPTION OF EMBODIMENTS

Hereinafter, embodiments for carrying out the present disclosure will be described with reference to the drawings. In each drawing, the same components are indicated by the same reference numerals, and redundant descriptions may be omitted.

### [Plasma Processing Apparatus]

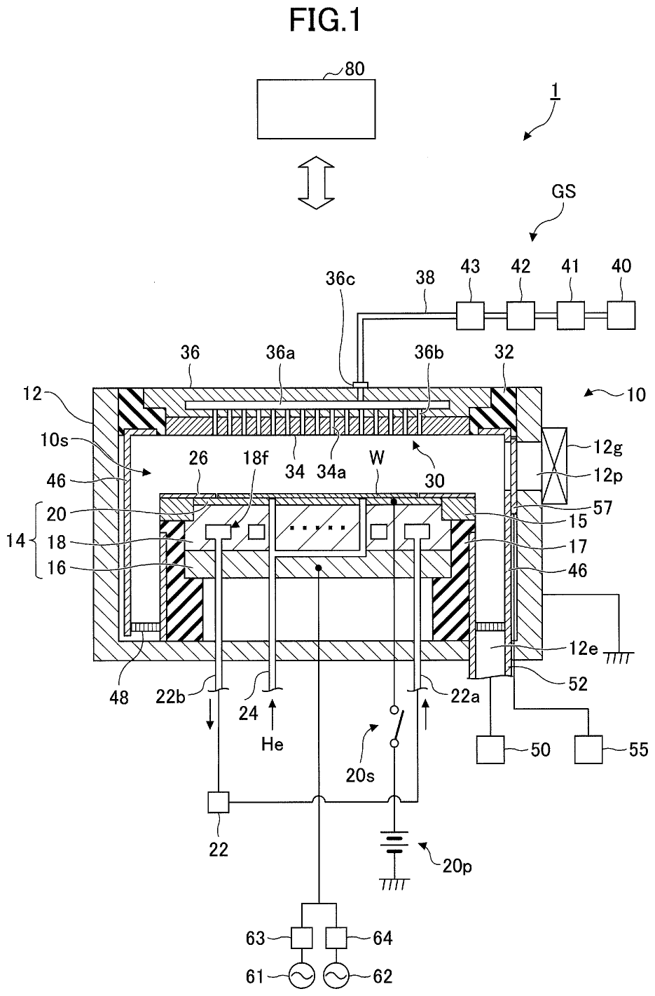

FIG. 1 is a schematic diagram illustrating a plasma processing apparatus 1 according to an embodiment. The plasma processing apparatus 1 illustrated in FIG. 1 is a capacitively coupled plasma type apparatus. The plasma processing apparatus 1 includes a chamber 10. The chamber 10 provides an interior space 10s therein.

The chamber 10 includes a chamber body 12. The chamber body 12 has a generally cylindrical shape. The interior space 10s is provided inside the chamber body 12. The chamber body 12 is formed of, for example, aluminum. On the inner wall surface of the chamber body 12, a film that is corrosion resistant to plasma is provided. The corrosion-resistant film has a multilayered film structure formed of ceramic, such as yttrium oxide or mullite, and resin. The structure of the multilayered film will be described below.

A passage 12p is formed in the side wall of the chamber body 12. The passage 12p can be opened and closed by a gate valve 12g. The gate valve 12g is provided along the side wall of the chamber body 12.

The passage 12p formed in the side wall of the chamber body 12 can be opened and closed by a shutter 57 in the interior space 10s. When a substrate W is conveyed between the interior space 10s and the exterior of the chamber 10, the gate valve 12g is opened and the shutter 57 is lowered by actuating a lifter 55, to load the substrate W from the passage 12p into the chamber 10.

A support 17 is provided on the bottom of the chamber body 12. The support 17 is formed of an insulating material. The support 17 has a generally cylindrical shape. In the interior space 10s, the support 17 extends upward from the bottom of the chamber body 12. A member 15 is provided on the support 17. The member 15 is formed of an insulating material such as quartz. The member 15 may have a generally cylindrical shape. Alternatively, the member 15 may be an annular plate.

The plasma processing apparatus 1 further includes a substrate support platform, i.e., a mounting table 14 according to one exemplary embodiment. The mounting table 14 is supported by the support 17. The mounting table 14 is provided in the interior space 10s. The mounting table 14 is configured to support a substrate W inside the chamber 10, i.e., in the interior space 10s.

The mounting table 14 includes a base 18 and an electrostatic chuck 20 according to one exemplary embodiment. The mounting table 14 may further include an electrode plate 16. The electrode plate 16 is formed of a conductor such as aluminum, and is generally of a disk shape. The base 18 is provided on the electrode plate 16. The base 18 is formed of a conductor such as aluminum, and is generally of a disk shape. The base 18 is electrically connected to the electrode plate 16. The outer edge surface of the base 18 and the outer edge surface of the electrode plate 16 are surrounded by the support 17.

The electrostatic chuck 20 is provided on the base 18. An electrode is embedded in the electrostatic chuck 20. The electrode of the electrostatic chuck 20 is connected to a direct-current (DC) power supply 20p via a switch 20s. When voltage is applied from the DC power supply 20p to the electrode of the electrostatic chuck 20, electrostatic attractive force is generated between the electrostatic chuck 20 and a substrate W. The substrate W is held to the electrostatic chuck 20 by the electrostatic attractive force.

The edge of the electrostatic chuck 20 and the outer edge surface of the base 18 are surrounded by the member 15. The electrostatic chuck 20 supports the substrate W and an edge ring 26 according to one exemplary embodiment. The edge ring 26 may also be referred to as a focus ring. The substrate W has a general disk shape, for example, and is placed on the electrostatic chuck 20. The edge ring 26 is placed on the electrostatic chuck 20 to surround the edge of the substrate W. The outer edge portion of the edge ring 26 may extend on the member 15.

A flow passage 18f is provided in the base 18. A heat exchange medium (e.g., refrigerant) is supplied to the flow passage 18f from a chiller unit 22 provided outside the chamber 10 through a pipe 22a. The heat exchange medium supplied to the flow passage 18f is returned to the chiller unit 22 via a pipe 22b. In the plasma processing apparatus 1, a temperature of a substrate W placed on the electrostatic chuck 20 is regulated by heat exchange between the heat exchange medium and the base 18.

The plasma processing apparatus 1 is provided with a gas supply line 24. The gas supply line 24 supplies a heat transfer gas (e.g., He gas) from a heat transfer gas supply mechanism to a gap between the upper surface of the electrostatic chuck 20 and the back surface of the substrate W.

The plasma processing apparatus 1 further includes an upper electrode 30. The upper electrode 30 is provided above the mounting table 14. The upper electrode 30 is supported at an upper portion of the chamber body 12 via a member 32. The member 32 is formed of an insulating material. The upper electrode 30 and the member 32 occlude the opening of the upper portion of the chamber body 12.

The upper electrode 30 may include a top plate 34 and a support 36. The lower surface of the top plate 34 is exposed to the interior space 10s, and defines the interior space 10s. The top plate 34 may be formed of a low resistance conductor or semiconductor with low Joule heat generation. Multiple gas discharge holes 34a are formed on the top plate 34. The multiple gas discharge holes 34a penetrate the top plate 34 in a thickness direction of the top plate 34.

The mounting table 14 is an electrode to which a second radio frequency power supply 62 is connected, and functions as a cathode (a lower electrode). The upper electrode 30 is a counter electrode of the electrode connected to the second radio frequency power supply 62. The chamber 10 is electrically grounded, and the inner wall of the chamber 10 functions as an anode paired with the lower electrode (mounting table 14).

The support 36 removably supports the top plate 34. The support 36 is formed of a conductor such as aluminum. Inside the support 36, a gas diffusion chamber 36a is provided. Multiple gas holes 36b are formed in the support 36. The multiple gas holes 36b extend downward from the gas diffusion chamber 36a. The multiple gas holes 36b communicate with the multiple gas discharge holes 34a, respectively. A gas inlet 36c is formed on the support 36. The gas inlet 36c is communicated with the gas diffusion chamber 36a. A gas supply line 38 is connected to the gas inlet 36c.

A gas supply section GS is connected to the gas supply line 38. The gas supply section GS includes gas sources 40, valves 41, flow controllers 42, and valves 43. The gas sources 40 are connected to the gas supply line 38 via the valves 41, the flow controllers 42, and the valves 43. Each of the valves 41 and the valves 43 may be an open/close valve. Each of the flow controllers 42 is a mass flow controller or a pressure-controlled flow controller. Each of the gas sources 40 is connected to the gas supply line 38 via a corresponding open/close valve of the valves 41, a corresponding flow controller of the flow controllers 42, and a corresponding open/close valve of the valves 43.

In the plasma processing apparatus 1, a deposition shield 46 is removably provided along the inner wall surface of the chamber body 12. The deposition shield 46 is also provided around the outer peripheral surface of the support 17. The deposition shield 46 prevents etching by-products from adhering to the chamber body 12. The deposition shield 46 is formed by, for example, forming a corrosion resistant film on the surface of a member formed of aluminum. The corrosion resistant film may be a film formed from a ceramic such as yttrium oxide.

A baffle plate 48 is provided between the outer side wall of the support 17 and the inner side wall of the chamber body 12. The baffle plate 48 is formed by, for example, forming a corrosion resistant film on the surface of a member formed of aluminum. The corrosion resistant film may be a film formed from a ceramic such as yttrium oxide. Multiple through-holes are formed in the baffle plate 48. An exhaust port 12e is provided below the baffle plate 48, at the bottom of the chamber body 12. An exhaust device 50 is connected to the exhaust port 12e via an exhaust pipe 52. The exhaust device 50 includes a pressure regulating valve and a vacuum pump such as a turbomolecular pump.

The plasma processing apparatus 1 further includes a first radio frequency (RE′) power supply 61. The first radio frequency power supply 61 may also be referred to as a “first RF power supply 61”. The first RF power supply 61 is configured to generate first radio frequency electric power for plasma generation. The frequency of the first radio frequency electric power is, for example, a frequency in the range of 27 MHz to 100 MHz.

The first radio frequency power supply 61 is electrically connected to the base 18 via a matcher 63. The matcher 63 includes matching circuitry. The matching circuitry of the matcher 63 is configured to cause impedance of the load side (lower electrode side) of the first radio frequency power supply 61 to match output impedance of the first radio frequency power supply 61. In another embodiment, the first radio frequency power supply 61 may be electrically connected to the upper electrode 30 via the matcher 63.

The plasma processing apparatus 1 may further include a second radio frequency power supply 62. The second radio frequency power supply 62 may also be referred to as a “second RF power supply 62”. The second RF power supply 62 is configured to generate second radio frequency electric power for drawing ions. That is, the second radio frequency electric power has a frequency that is suitable for mainly drawing positive ions into the substrate W. The frequency of the second radio frequency electric power is, for example, a frequency in the range of 400 kHz to 13.56 MHz.

The second radio frequency power supply 62 is electrically connected to the base 18 via a matcher 64. The matcher 64 includes matching circuitry. The matching circuitry of the matcher 64 is configured to cause impedance of the load side (lower electrode side) of the second radio frequency power supply 62 to match output impedance of the second radio frequency power supply 62.

The plasma processing apparatus 1 may further include a controller 80. The controller 80 may be a computer including a processor, a storage device such as a memory, an input device, a display device, an input/output interface of signals, or the like. The controller 80 controls each part of the plasma processing apparatus 1. In the controller 80, an operator can perform, by using the input device, input operations of commands to manage the plasma processing apparatus 1. The controller 80 can also display an operating status of the plasma processing apparatus 1 on the display device. The storage device of the controller 80 stores a control program and recipe data. The control program is executed by the processor of the controller 80 to cause the plasma processing apparatus 1 to perform various processes. By the processor of the controller 80 executing the control program and controlling each part of the plasma processing apparatus 1 in accordance with the recipe data, various processes, such as a plasma processing method, are performed in the plasma processing apparatus 1.

### [Structure of Multilayered Film]

The inner wall of the chamber 10 (chamber body 12) is an example of a member that is connected to a ground potential and forms an anode paired with the electrode to which the second radio frequency power supply 62 is connected. Other examples of the member forming the anode paired with the electrode to which the second radio frequency power supply 62 is connected include the deposition shield 46, the baffle plate 48, and the shutter 57. On the surface of the member forming the anode, a multilayered film structure that adjusts capacitance of the member forming the anode is formed. Hereinafter, a case in which the member forming the anode is the inner wall of the chamber 10 will be described.

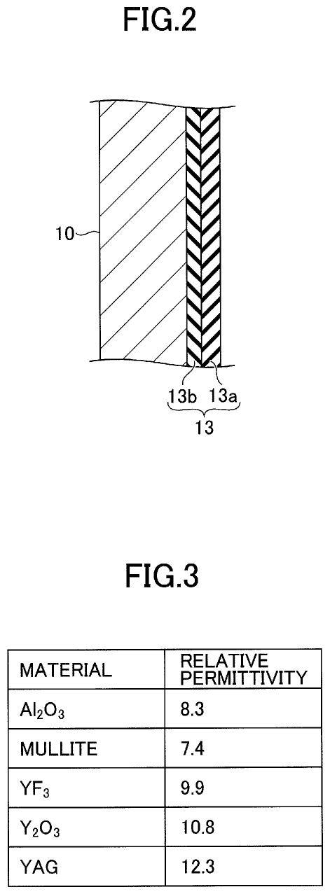

FIG. 2 illustrates an example of the inner wall of the chamber 10 according to the present embodiment. On the inner wall of the chamber 10, a multilayered film structure 13 is formed. The multilayered film structure 13 adjust capacitance of the inner wall of the chamber 10. The multilayered film structure 13 is formed by laminating an yttrium oxide (Y₂O₃) film 13a and a mullite film 13b. The mullite film 13b is coated on the inner wall of the chamber 10, and the yttrium oxide (Y₂O₃) film 13a is coated on the mullite film 13b. The yttrium oxide film 13a is an example of a first film formed on the outermost layer of the multilayered film structure 13 which is coated on the surface of the member constituting the anode. The mullite film 13b is an example of a second film coated on the surface of the member constituting the anode, and the second film has a lower relative permittivity (dielectric constant) than the first film. That is, the multilayered film structure 13 is formed of the first film and the second film having a lower relative permittivity than the first film. The second film is sandwiched between the first film and the surface of the member constituting the anode.

The mullite film 13b and the yttrium oxide film 13a may be sequentially coated onto the inner wall of the chamber 10 by thermal spraying. However, the coating method of the multilayered film structure 13 is not limited thereto, and the multilayered film structure 13 may be coated by vapor deposition or other known methods. Vapor deposition may include, for example, deposition by chemical vapor deposition (CVD) or a resin coating method.

FIG. 3 is a diagram illustrating relative permittivities of materials to be thermal sprayed according to the present embodiment. For example, the relative permittivity εᵣ of Y₂O₃ is “10.8”, and the relative permittivity εᵣ of Mullite is “7.4”. A measured value of the relative permittivity εᵣ of a multilayered film of the yttrium oxide film 13a and the mullite film 13b was “8.6”, in a case of the same film thickness. In the following description, the relative permittivity of the multilayered film formed of multiple films, such as the yttrium oxide film 13a and the mullite film 13b, may be referred to as a “composite relative permittivity”. Note that the relative permittivity (including the composite relative permittivity) of each film described in the present embodiment is measured by making a thickness of each film the same.

Thus, if the multilayered film structure 13 is formed on the inner wall of the chamber 10, the permittivity can be reduced compared to a case in which only the yttrium oxide film 13a is coated on the inner wall of the chamber 10, and capacitance of the inner wall of the chamber 10 can be adjusted. Similarly, the multilayered film structure 13 may be formed on the outermost surface of the deposition shield 46, the baffle plate 48, and the shutter 57, which are examples of the members constituting the anode. This allows the permittivity to be reduced as compared to the case in which only the yttrium oxide film 13a is coated on these members, and capacitance of the members can be adjusted while maintaining plasma resistance of the members.

The multilayered film structure 13 coating the member constituting the anode may be formed of a first film and a second film having a lower relative permittivity than the first film, and is not limited to a set of the yttrium oxide film 13a and the mullite film 13b. For example, the first film formed on the outermost layer of the multilayered film structure 13 may be formed of yttrium aluminum garnet (YAG), which is a complex oxide of yttria, aluminum, and oxygen (Y₃Al₅O₁₂). In this case, the second film may be formed of at least one of yttrium oxide (Y₂O₃), yttrium fluoride (YF₃), alumina (Al₂O₃), and mullite, each of which is a material having a lower relative permittivity than yttrium aluminum garnet. This allows the composite relative permittivity of the multilayered film structure 13 to be lower than the relative permittivity of yttrium aluminum garnet formed on the outermost layer of the multilayered film structure 13. The above-mentioned materials are examples, and any material having a lower relative permittivity than the first film formed on the outermost layer of the multilayered film structure 13 can be selected as the second film. For example, a material coated on the outermost layer of the multilayered film structure 13 may be an alumina film, and a material having a relative permittivity lower than that of the alumina (e.g., mullite) may be coated under the alumina film. Also, it is preferable to select, as the first film, a material that is corrosion resistant to plasma. The second film may be a multilayered film formed of multiple materials having a lower relative permittivity than the first film.

### [Ion Sputtering]

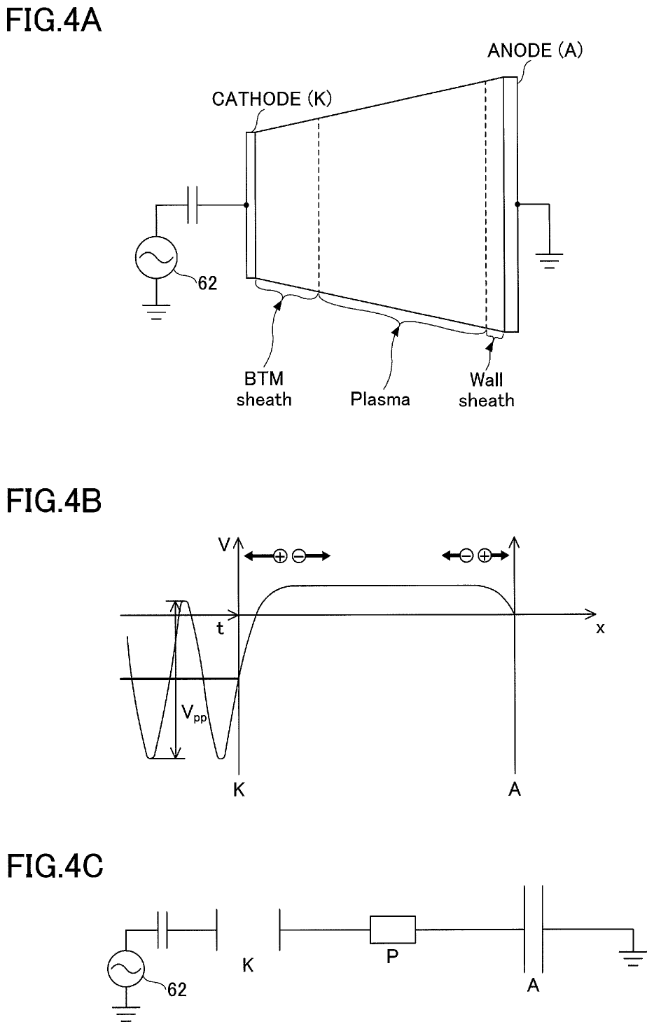

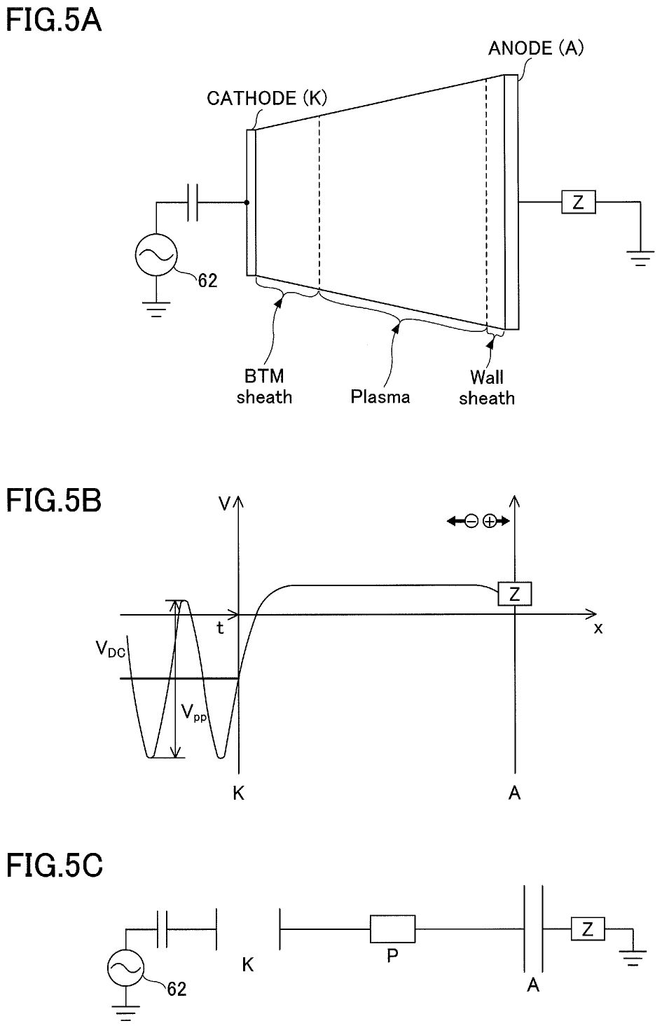

Next, ion sputtering will be described with reference to FIGS. 4A to 4C and FIGS. 5A to 5C. FIGS. 4A to 4C are diagrams illustrating ion sputtering occurring between a cathode and an anode according to a comparative example. FIGS. 5A to 5C are diagrams illustrating ion sputtering occurring on the multilayered film structure according to the present embodiment. In FIGS. 4A to 4C and FIGS. 5A to 5C, the cathode may be represented by a symbol “K”, and the anode may by represented by a symbol “A”.

The cathode is an electrode (mounting table 14) to which the second radio frequency power supply 62 is connected, and the anode is the inner wall of the chamber 10. By applying first radio frequency electric power from the first radio frequency power supply 61 to the mounting table 14, a discharge phenomenon occurs between the cathode and the anode, and a plasma is generated as illustrated in FIG. 4A. Then, a sheath (hereinafter referred to as a “BTM sheath”) is formed on the cathode K, and a sheath (hereinafter referred to as a “wall sheath”) is formed on the anode A. By applying second radio frequency electric power from the second RF power supply 62 to the mounting table 14, positive ions in the plasma are accelerated in the bottom sheath, as indicated by an arrow of a positive ion directed toward the cathode K illustrated in FIG. 4B. The accelerated positive ions collide with the substrate W to apply a predetermined plasma treatment, such as etching, to the substrate W. The thicker the bottom sheath is, the greater positive ions in the bottom sheath are accelerated. Thus, as the bottom sheath becomes thicker, processing such as etching is accelerated because force of collision of positive ions on the substrate W becomes greater and an etch rate and the like become higher.

Thus, when positive ions in the plasma are directed toward cathode K, the positive ions contribute to plasma processing. However, “ion sputtering”, which is a phenomenon in which positive ions directed toward the inner wall of the chamber 10 constituting the anode collide with the inner wall, causes damage to the inner wall and also becomes a cause of particles. Also, degree of ion sputtering is proportional to a thickness of the wall sheath formed on the inner wall of the chamber 10.

A relationship between an electric potential in plasma and movement of positive ions will be further described. The curve illustrated in the graph of FIG. 4B represents the electric potential. An intersection of the curve and a vertical axis on the right side of FIG. 4B indicates an electric potential at the anode A, and an intersection of the curve and a vertical axis on the left side of FIG. 4B indicates an electric potential at the cathode K. The electric potential in the plasma processing space between the anode A and the cathode K is the plasma potential. Because of the second radio frequency electric power applied to the cathode K, self-bias voltage is generated, and an average voltage at the cathode K becomes negative.

The plasma potential becomes higher than the electric potential of the inner wall of the chamber 10. As the inner wall of the chamber 10 is grounded, the electric potential of the anode A is zero. Thus, according to the potential difference between the plasma potential and the electric potential of the anode A, positive ions are accelerated in the wall sheath.

In this way, positive ions enter the anode A (inner wall), and the inner wall is bombarded with the positive ions. Accordingly, components of the film (yttria or the like) of the outermost layer formed on the chamber 10 peel off from the inner wall of the chamber 10, and fly onto the substrate W to form particles. Particles cause a short circuit of interconnects while processing a substrate, thereby reducing yield. Accordingly, it is desirable to minimize generation of particles in the chamber 10.

Conventionally, by increasing an area of the anode relative to the cathode, an amount of ion bombardment per unit area at the anode has been lowered.

In the present embodiment, by increasing the impedance of the anode side, the electric potential of the inner wall of the chamber 10 serving as an anode is increased to be greater than 0, and the potential difference between the plasma potential and the electric potential of the anode A is reduced. This reduces ion bombardment to the inner wall of the chamber 10 and reduces generation of particles. In order to increase the electric potential of the inner wall of the chamber 10, the multilayered film structure 13 formed of the first and second films is formed on the inner wall of the chamber 10. Accordingly, the multilayered film structure 13 can reduce permittivity of the inner wall of the chamber 10 and reduce capacitance of the inner wall of the chamber 10 compared to a case in which only the first film is formed on the inner wall. This increases the impedance on the anode side.

FIG. 5C is an equivalent circuit when the multilayered film structure 13 according to the present embodiment is used. FIG. 4C is an equivalent circuit according to the comparative example when a single coating of an yttrium oxide film is formed on the inner wall without using the multilayered film structure 13 according to the present embodiment. The multilayered film structure 13 according to the present embodiment has a first film and a second film, and the relative permittivity of the second film is lower than the relative permittivity of the first film. As illustrated in the equivalent circuit of FIG. 4C, in a case in which only the first film is coated on the inner wall of the chamber 10, the capacitance of the inner wall is larger than a case in which the multilayered film structure 13 is coated on the inner wall. Accordingly, as illustrated in FIG. 5C, the equivalent circuit according to the present embodiment differs in impedance Z on the anode side compared to the equivalent circuit according to the comparative example.

The impedance of the inner wall of the chamber 10, on which the multilayered film structure 13 (the first film and the second film) according to the present embodiment is coated, is denoted by Z_{A}, the impedance of the inner wall of the chamber 10 on which only the first film is coated is denoted by Z₀, and the difference between Z_{A} and Z₀ (=Z_{A}−Z₀) is denoted by Z.

Let the capacitance of the first film to be coated on the inner wall of the comparative example be C_{A1} [F], and the capacitance of the multilayered film structure 13 to be coated on the inner wall of the present embodiment be C_{A2} [F].

C_{A1} is given by the following equation (1), and C_{A2} is given by the following equation (2).

$$\begin{matrix}{C}_{A 1} = {ɛ}_{0} {ɛ}_{A 1} \frac{S}{{d}_{A 1}} & ( 1 ) \\ {C}_{A 2} = {ɛ}_{0} {ɛ}_{A 2} \frac{S}{{d}_{A 2}} & ( 2 )\end{matrix}$$

where ε₀ is the vacuum permittivity (8.85×10⁻¹² [F/m]), ε_{A1} is the relative permittivity of the first film of the comparative example, and ε_{A2} is the composite relative permittivity of the multilayered film structure 13 (first and second films). The symbol d_{A1} indicates the thickness [m] of the first film of the comparative example, and the symbol d_{A2} indicates the thickness [m] of the multilayered film structure 13. Let the thickness of the first film of the comparative example and the thickness of the multilayered film structure 13 be the same, that is, d_{A1}=d_{A2}. S indicates the area of the anode [m²]. As ε_{A1} is greater than ε_{A2} (ε_{A1}>ε_{A2}), based on the equations (1) and (2), C_{A1}>C_{A2} is derived.

The impedance is given by the following equation (3).

$$Z = - \frac{1}{C ω} j \qquad ( 3 )$$

Because C_{A1}>C_{A2}, C_{A2}−C_{A1}<0, and therefore Z=Z_{A}−Z₀>0, based on the equation (3). That is, as illustrated in the equivalent circuit of FIG. 5C, the impedance of the inner wall coated with the multilayered film structure 13 according to the present embodiment is greater by Z compared to the impedance of the inner wall in the comparative example that is coated with only the first film. As a result, in the present embodiment, the electric potential of the anode becomes higher than zero, as illustrated in FIG. 5B.

Accordingly, the potential difference between the plasma potential and the electric potential of the anode can be reduced by the multilayered film structure 13 according to the present embodiment.

Thus, acceleration of positive ions in the wall sheath of the anode can be reduced, and the inner wall of the chamber 10 is prevented from being bombarded with ions, thereby reducing generation of particles.

As described above, in the present embodiment, a sheath is regarded as a capacitor, and by forming the multilayered film structure 13 of the first film and the second film having a lower relative permittivity than the first film on the inner wall of the chamber 10, the capacitance of the members constituting the anode is reduced. As the impedance is increased, the electric potential of the anode can be brought closer to the plasma potential. By reducing the potential difference between the plasma potential and the electric potential of the inner wall, wear of the chamber inner wall due to ion bombardment can be reduced.

The multilayered film structure 13 coated on the inner wall of the chamber 10 has been described above. The multilayered film structure 13 according to the above-described embodiments is an example, and various modifications are contemplated. For example, for each member comprising the anode, the multilayered film structure 13 may be formed of a different combination of films. For example, by employing a different combination of films as the multilayered film structure formed on the outermost layer of the deposition shield 46, with respect to the combination of films as the multilayered film structure 13 formed on the outermost layer of the inner wall of the chamber 10, the composite relative permittivity may be changed to vary the impedance at the anode side.

This allows an amount of ion bombardment for each member constituting the anode to be made different. Alternatively, the materials of the first and second films may differ within a single member constituting the anode. The materials of the first and second films may be changed stepwise. Alternatively, the materials of the first and second films may be changed continuously, that is, the first and second films may include a gradation of materials. This allows an amount of ion bombardment to be made different within a single member constituting the anode.

The plasma processing apparatus according to the present embodiment disclosed herein should be considered exemplary in all respects and not limiting. The above embodiments may be modified and enhanced in various forms without departing from the appended claims and spirit thereof. Matters described in the above embodiments may take other configurations to an extent not inconsistent, and may be combined to an extent not inconsistent.

The plasma processing apparatus 1 according to the present disclosure is applicable to any of the following types of devices: an atomic layer deposition (ALD) device, a capacitively coupled plasma (CCP) type device, an inductively coupled plasma (ICP) type device, a radial line slot antenna (RLSA) type device, an electron cyclotron resonance (ECR) plasma type device, and a helicon wave plasma (HWP) type device.

Further, the plasma processing apparatus 1 is not limited to a plasma etching apparatus, and may be an apparatus that applies a predetermined process, such as deposition and etching, to a substrate by using plasma. For example, the plasma processing apparatus 1 may be a deposition apparatus, an ashing apparatus, a doping apparatus, a plasma ALD apparatus, a plasma CVD apparatus, or the like.

What is claimed is:

1. A plasma processing apparatus comprising:
a gas supply section;
a first radio frequency power supply for plasma generation;
a second radio frequency power supply for drawing ions;
an electrode coupled to the second radio frequency power supply; and
a member serving as an anode paired with the electrode; wherein
a multilayered film structure is formed on a surface of the member, to adjust capacitance of the member.

2. The plasma processing apparatus according to claim 1, wherein the multilayered film structure includes a first film and a second film having a lower relative permittivity than the first film.

3. The plasma processing apparatus according to claim 2, wherein the second film is disposed between the first film and the surface of the member.

4. The plasma processing apparatus according to claim 1, wherein the member is an inner wall of a chamber, a deposition shield, a baffle plate, or a shutter.
